(19) United States
(12) Patent Application Publication
(10) Pub. No.: US 2013/0101832 A1
(43) Pub. Date: Apr. 25, 2013

(54) NOBLE METAL COATING AND MANUFACTURING METHOD THEREOF

(71) Applicant: NGK INSULATORS, LTD., Nagoya-City (JP)

(72) Inventors: Takaaki KOIZUMI, Tajimi-City (JP); Naoki OGAWA, Tokai-City (JP); Akifumi MORISHITA, Nagoya-City (JP)

(73) Assignee: NGK INSULATORS, LTD., Nagoya-City (JP)

(21) Appl. No.: 13/650,513

(22) Filed: Oct. 12, 2012

(30) Foreign Application Priority Data
Oct. 20, 2011 (JP) 2011-230825

(51) Int. Cl. B32B 15/04; B05D 3/02; H01L 39/24; H01L 41/22; H01L 39/02; B05D 1/18; B05D 5/12

(52) U.S. Cl. 428/325; 427/443.1; 427/383.5; 427/299; 427/100; 505/470; 427/123; 427/125; 505/236; 428/336; 427/62

(57) ABSTRACT

The noble metal coating of the present invention is formed on a ceramic substrate. The noble metal coating has a thickness of less than 2 μm and comprises a matrix metal and a ceramic fine particle. The matrix metal includes at least one metal selected from a group consisting of Pt, Pd, Ru, Rh, Os, Ir and Au as a main component. The content of the ceramic fine particle is preferably 3 to 30 parts by weight with respect to 100 parts by weight of the matrix metal. The ratio between the average particle size of the ceramic fine particle and the thickness of the noble metal coating is preferably 1/1.5 to 1/400.

### CROSS-REFERENCE TO RELATED APPLICATIONS

This application claims priority to Japanese Patent Application No. 2011-230825 filed on Oct. 20, 2011. The entire disclosure of Japanese Patent Application No. 2011-230825 is hereby incorporated herein by reference.

### BACKGROUND

1. Technical Field

The present invention relates to a noble metal coating and a manufacturing method thereof, and a laminate including a noble metal coating and a manufacturing method thereof.

2. Description of the Related Art

Recently, there is a demand for making a noble metal film thin on a ceramic substrate in a ceramic electronic component, in order to maintain or improve the characteristics and to reduce the cost. Electroless plating has been attracting attention as a method for manufacturing a thin metal film, but it is difficult to apply a conventional plating film due to deterioration of the adhesive force.

In electroless plating, typically, a surface of a substrate is roughened, a catalyst is applied thereto, and a plating film is then caused to precipitate thereon through a catalytic action in the plating solution. The rough surface of the substrate formed by the surface roughening treatments functions as anchor, and, thus, the adhesion between the plating film and the substrate is maintained. However, in order that impurities contained in the plating film will be removed in the form of gas, thermal treatments may be performed at no less than the temperature at which grains in the plating film grow. In that case, the plating material at the anchor portion may be sucked up as the grains grow, and the anchoring effect may be lowered, and, thus, adhesive strength may not be maintained. In particular, in the case of a thin film having a film thickness of less than 2 μm, when thermal treatments at a high temperature are required after the film formation, the grain growth may cause a problem in which the surface smoothness deteriorates because the plating film is made convex in the shape of domes or in which the coverage of the plating film deteriorates because domes are partially broken.

JP H5-343259A discloses a method for manufacturing an electroless plating film that can be joined with a ceramic substrate without surface roughening treatments on the ceramic substrate, wherein composite plating is applied in which an electroless plating material is mixed with a glass powder, the method improving the adhesion to the substrate by means of the glass softened through thermal treatments. However, the plating film may be peeled away due to the internal stress that is generated during the plating film formation, and the applicable plating options are limited. Moreover, the glass component may react with another component and cause deterioration in the characteristics.

Japanese Patent No. 3242459 discloses a method for manufacturing a ceramic wiring board, including the steps of forming a resistor layer by firing on a ceramic substrate whose surface is provided with a conductor layer, and then forming a metal coating on the surface of the conductor layer by plating, wherein the conductor layer provided on the ceramic substrate is formed by plating, and contains at least either ceramic particles or metal particles dispersed therein.

However, it is preferable that the thickness of the conductor layer containing ceramic particles or the like is 2 μm or more, and only layers having a thickness of 3 to 6 μm are formed in specific working examples. Furthermore, regarding the conductor layer, research has been conducted only on copper and nickel, and, in particular, no research has been conducted on a noble metal coating such as Pt coating that is compatible with an oxide film requiring firing in O₂.

The present invention was made in view of these problems of conventional techniques, and it is an object thereof to provide a noble metal coating in which the film thickness is less than 2 μm and in which the adhesion to a substrate is maintained even when thermal treatments are performed in an oxidizing atmosphere at no less than the temperature at which metal grains contained in the noble metal coating grow (e.g., thermal treatments unavoidable for removing impurities contained in the plating film in the form of gas, etc.), and a manufacturing method thereof.

It is another object of the present invention to provide a laminate including at least a noble metal coating and a ceramic substrate, the noble metal coating having a film thickness of less than 2 μm and having an adhesion to a ceramic substrate that is maintained even when thermal treatments are performed in an oxidizing atmosphere at no less than the temperature at which metal grains contained in the noble metal coating grow (e.g., thermal treatments unavoidable for removing impurities contained in the plating film in the form of gas, etc.), and a manufacturing method thereof.

### SUMMARY

Accordingly, the present invention is directed to a noble metal coating formed on a ceramic substrate. The noble metal coating has a thickness of less than 2 μm and comprises a matrix metal and a ceramic fine particle. The matrix metal includes at least one metal selected from a group consisting of Pt, Pd, Ru, Rh, Os, Jr and Au as a main component.

Preferably, the ceramic fine particle contains at least one ceramic selected from a group consisting of ceria, zirconia, yttria, alumina, titania, spinel (magnesium aluminate, nickel aluminate), yttria-stabilized zirconia, ceria-stabilized zirconia, TiC, and TiN.

Preferably, the content of said ceramic fine particle is 3 to 30 parts by weight with respect to 100 parts by weight of said matrix metal.

Preferably, the average particle size of said ceramic fine particle is 5 to 100 nm.

Preferably, the ratio between said average particle size of said ceramic fine particle and said thickness of said noble metal coating is 1/1.5 to 1/400.

Preferably, the noble metal coating is thermally treated at a temperature which is greater than or equal to a particle growth initiating temperature for said matrix metal in said noble metal coating.

Preferably, the noble metal coating is formed by plating.

Additionally, the present invention is directed to a method for manufacturing above-mentioned noble metal coating. The method comprises: a dispersion step of dispersing said ceramic fine particle in a plating solution that contains a metal ion corresponding to said matrix metal; and a plating step of forming said noble metal coating having a thickness of less than 2 μm on said ceramic substrate using said plating solution in which said ceramic fine particle is dispersed.

Preferably, the method for manufacturing the noble metal coating further comprises a thermal treatment step of performing a thermal treatment at a temperature which is greater than or equal to a particle growth initiating temperature for said matrix metal.

Preferably, the method for manufacturing the noble metal coating further comprises a surface roughening step of performing a surface roughening treatment on said ceramic substrate before said plating step.

Preferably, in the method for manufacturing the noble metal coating, a pH of said plating solution in said plating step is 10 to 14.

Preferably, in the method for manufacturing the noble metal coating, a temperature of said plating solution is 30 to 85° C.

Further, the present invention is directed to a laminate comprises above-mentioned noble metal coating and a ceramic substrate.

Preferably, the laminate further comprises a ceramic layer on a surface of said noble metal coating in an opposite side to said ceramic substrate. The noble metal coating and said ceramic layer are preferably co-fired. The laminate is preferably a dielectric element, a piezoelectric/electrostrictive element, a pyroelectric element, a thermoelectric element, a semiconductor element, a superconductor element, or an ion conductor element, and the laminate without the ceramic layer may be used as a gas sensor for gas such as oxygen or NOx.

The present invention provides a noble metal coating in which the film thickness is less than 2 μm and in which the adhesion to a ceramic substrate is maintained or improved even when thermal treatments are performed in an oxidizing atmosphere at no less than the temperature at which grain growth of the metal contained in the noble metal coating starts, and a manufacturing method thereof. Accordingly, the noble metal coating can be fired in an oxidizing atmosphere, and the cost can be reduced because the film thickness becomes thinner.

Furthermore, according to the laminate of the present invention, ceramic requiring sintering at a high temperature (e.g., 1700° C. or less, approximately 800 to 1700° C.) can be layered on the noble metal coating, and the laminate can be co-fired in an oxidizing atmosphere. Accordingly, the laminate is useful as a ceramic element in which the adhesive force is high when the above-described noble metal coating is used as an electrode, and in which, since the electrode is thin, the influence of the electrode is reduced, the characteristics are improved, and the cost is reduced.

### DETAILED DESCRIPTION OF EMBODIMENTS

(1) Noble Metal Coating

A noble metal coating of the present invention is formed on a ceramic substrate, contains a matrix metal containing, as a main component, at least one type of metal selected from the group consisting of Pt, Pd, Ru, Rh, Os, Ir, and Au, and ceramic fine particles, and has a film thickness of less than 2 μm. The noble metal coating may be formed via any intermediate layer on the ceramic substrate.

<Matrix Metal>

The matrix metal contains, as a main component, at least one type of metal selected from the group consisting of Pt, Pd, Ru, Rh, Os, Ir, and Au. Note that, in this specification, “containing as a main component” may refer to containing that component in an amount of 60 wt % or more, 80 wt % or more, or 90 wt % or more. The metal contained as a main component in the matrix metal may be a mixture of two or more types of the above-listed metals. In this case, that mixture is contained as a main component in an amount corresponding to the sum of the contents of those metals.

The noble metal coating of the present invention may contain any metal other than the above, such as Cu, Ni, Cr, and the like, as another component.

If the noble metal coating of the present invention contains the above-listed metal(s) as a main component, a noble metal coating is obtained that has a high electrical conductivity and that can be fired in an oxidizing atmosphere. Since the noble metal coating can be fired in an oxidizing atmosphere at a high temperature, it can be co-fired, for example, with ceramic requiring sintering at a high temperature (e.g., 1700° C. or less) such as ceramic having a perovskite structure, and, thus, the manufacturing process can be simplified, and a laminate having a high adhesion to such ceramic can be provided.

<Ceramic Fine Particles>

The noble metal coating of the present invention contains ceramic fine particles in the matrix metal. Accordingly, it seems that, in thermal treatments at no less than the temperature at which grain growth of matrix metal particles starts, the grain boundary migration of the matrix metal particles is pinned by the ceramic fine particles functioning as fillers, and, thus, the grain growth is suppressed.

There is no particular limitation on the ceramic fine particles contained in the noble metal coating of the present invention, and any ceramic fine particles may be used as long as they do not react with the matrix metal or the electroless plating solution, and are dispersed in the electroless plating solution. It is more preferable that the ceramic fine particles are uniformly dispersed in the entire electroless plating solution. In this example, “dispersed in the electroless plating solution” may refer to a state in which a metal coating containing the ceramic fine particles can be formed by electroless plating. Since the noble metal coating of the present invention has a film thickness that is as thin as less than 2 μm, if the ceramic fine particles are uniformly dispersed in the entire electroless plating solution, the grain boundary migration of the matrix metal particles can be more effectively pinned, and the grain growth can be more effectively suppressed.

Moreover, since the noble metal coating of the present invention contains the matrix metal containing, as a main component, at least one type of metal selected from the group consisting of Pt, Pd, Ru, Rh, Os, Ir, and Au, the ceramic fine particles have to be dispersed in the matrix metal electroless plating solution containing these metals as a main component. Typically, such a plating solution in many cases has a pH of 10 or more, and, thus, it is preferable that the ceramic fine particles can be dispersed, in particular, in a plating solution having a pH of 10 or more.

Specific examples of the ceramic fine particles preferably include fine particles of: oxide such as ceria, zirconia, yttria, alumina, titania, spinel (magnesium aluminate, nickel aluminate), yttria-stabilized zirconia, and ceria-stabilized zirconia; titanium carbide; and titanium nitride. These types of ceramic fine particles may be used alone or in a combination of two or more types. As the ceramic fine particles, ceria, zirconia, yttria, alumina, titania, or spinel is particularly preferable.

The content of the ceramic fine particles is, for example, 3 to 30 parts by weight, preferably 3 to 20 parts by weight, and more preferably 3 to 15 parts by weight, with respect to 100 parts by weight of the matrix metal. If the content of the ceramic fine particles is set to such a range, even when thermal treatments are performed at no less than the temperature at which grain growth of matrix metal particles starts in order to remove impurities contained in the coating in the form of gas, the grain boundary migration of the matrix metal particles can be more effectively pinned, and the grain growth can be more effectively suppressed. Note that the content of the ceramic fine particles with respect to 100 parts by weight of the matrix metal can be determined by component analysis after the plating film formation, although it may depend on plating thickness, particle size and electrical resistance of noble metal particles after the thermal treatments, and other characteristic values of the noble metal coating. Specific examples of the evaluation method include fluorescent X-ray spectrometry, emission spectrometry by ICY or glow discharge, and mass spectrometry.

The average particle size of the ceramic fine particles added is preferably 5 to 100 nm, more preferably 10 to 70 nm, and even more preferably 20 to 60 nm, at the time of the addition to the electroless plating solution and/or after the firing, although it may depend on the plating film thickness. If the average particle size of the ceramic fine particles is set to such a range, even when thermal treatments are performed at no less than the temperature at which grain growth of matrix metal particles starts, the grain boundary migration of the matrix metal particles can be more effectively pinned, and the grain growth can be more effectively suppressed. Note that the average particle size of the ceramic fine particles can be determined in advance by, for example, direct observation using an electron microscope, or acoustic or optical measurement using a particle size analyzer.

The ratio between the average particle size of the ceramic fine particles and the film thickness of the noble metal coating (average particle size of ceramic fine particles)/(film thickness of metal coating) is preferably 1/1.5 to 1/400, more preferably 1/3 to 1/100, and even more preferably 1/5 to 1/20. If the ratio between the average particle size of the ceramic fine particles and the film thickness of the metal coating is set to such a range, even when thermal treatments are performed at no less than the temperature at which grain growth of matrix metal particles starts, the grain boundary migration of the matrix metal particles can be more effectively pinned, and the grain growth can be more effectively suppressed. Note that the film thickness of the noble metal coating can be determined from the concentration of the plating solution used.

<Ceramic Substrate>

The ceramic substrate on which the noble metal coating of the present invention is formed is an insulating component, and examples thereof include a material obtained by firing an insulating ceramic. As the insulating ceramic, for example, at least one type of material selected from the group consisting of zirconia, alumina, magnesia, spinel, mullite, aluminum nitride, and silicon nitride is used. Zirconia includes materials that are stabilized or partially stabilized by yttrium or the like added.

The ceramic substrate may be surface-roughened, as will be described later. In this case, the rough surface of the substrate formed by the surface roughening treatments functions as anchor, and the adhesion between the plating film and the substrate is easily maintained. Since the noble metal coating of the present invention contains the ceramic fine particles, even when thermal treatments are performed at no less than the “temperature at which grains in the plating film grow” in order to remove impurities contained in the plating film in the form of gas, the plating material at the anchor portion is suppressed from being sucked up as the grains grow, and the anchoring effect is not lowered. Accordingly, the adhesive strength is more effectively maintained. The adhesive strength is, for example, 1.5 N/mm² or more, preferably 2.5 N/mm² or more, more preferably 4.0 N/mm² or more, and particularly preferably 5.2 N/mm² or more, according to measurement by the Sebastian method.

Since the noble metal coating of the present invention contains the ceramic fine particles, the film thickness of the metal coating can be as thin as less than 2 μm. The film thickness can be preferably 1 μm or less, more preferably 0.7 μm or less, and even more preferably 0.5 μm or less. The noble metal coating of the present invention has a coverage of 80% or more, preferably 90% or more, more preferably 95% or more, and particularly preferably 99% or more, even when thermal treatments are performed at no less than the temperature at which grain growth of matrix metal particles starts. Note that the coverage can be determined by image analysis through transmitted light observation on the metal coating using a microscope.

The noble metal coating of the present invention is preferably thermally treated at no less than the temperature at which grain growth of the matrix metal starts. In this example, “no less than the temperature at which grain growth of the matrix metal starts” may refer to a temperature of Tm/3 (K) or more, or Tm/2 (K) or more. Here, Tm refers to the temperature at which grains of the metal contained as a main component of the matrix metal grow. The grain growth may be also referred to as crystal grain growth. If the noble metal coating is, for example, fired at 800° C. to 1500° C. for approximately 1 to 5 hours after the film formation, impurities contained in the coating are removed in the form of gas.

Since the noble metal coating of the present invention has a film thickness that is as thin as less than 2 μm, even when an expensive noble metal is used as the matrix metal, the material cost can be reduced. Furthermore, when the noble metal coating of the present invention is used as an electrode of a ceramic element, a ceramic element with improved characteristics, in which the influence of the electrode is reduced, can be provided. It is preferable that the noble metal coating of the present invention is formed by plating.

(2) Method For Manufacturing Noble Metal Coating

A method for manufacturing the noble metal coating of the present invention includes: a dispersion step of dispersing the ceramic fine particles in a plating solution that contains metal ions corresponding to the matrix metal; and a plating step of forming a plating film having a thickness of less than 2 μm on a ceramic substrate using the plating solution in which the ceramic fine particles are dispersed. It is preferable that the noble metal coating of the present invention is manufactured by electroless plating. Various conditions in the electroless plating are set for each matrix metal material so as to cause precipitation of that material.

<Dispersion Step>

In the dispersion step, the ceramic fine particles are dispersed in the plating solution that contains metal ions corresponding to the matrix metal. It is preferable that the plating solution is adjusted in pH using an alkaline aqueous solution such as ammonia solution such that the ceramic fine particles are dispersed. The plating solution has, for example, a pH of 5.5 to 14, and preferably a pH of 10 or more. It is sufficient that the ceramic fine particles are not deposited in visual inspection, and, preferably, the ceramic fine particles are uniformly dispersed such that no agglomerate is observed.

The content of the matrix metal in the plating solution is, for example, 0.8 to 15.0 g/L, preferably 0.8 to 3.0 g/L, and more preferably 1.5 to 2.5 g/L, at room temperature (e.g., 20° C.). Furthermore, the content of the ceramic fine particles in the plating solution is, for example, 0.5 to 10 wt %, preferably 1 to 7 wt %, and more preferably 2 to 5 wt %. If the contents of the matrix metal and the ceramic fine particles in the plating solution are set to such ranges, even when thermal treatments are performed at no less than the temperature at which grain growth of matrix metal particles starts in order to remove impurities contained in the coating in the form of gas, a plating film is more easily obtained in which the grain boundary migration of the matrix metal particles can be more effectively pinned and the grain growth can be more effectively suppressed.

<Plating Step>

In the plating step, a plating film having a thickness of less than 2 μm is formed on a ceramic substrate using the plating solution in which the ceramic fine particles are dispersed, which was manufactured in the dispersion step. With this plating step, a coating containing the ceramic fine particles and the matrix metal can be manufactured on a surface of the ceramic substrate. Specifically, the plating can be performed by immersing the substrate in an electroless plating solution prepared such that a metal film having a desired thickness can be formed, and allowing it to stand therein for approximately 0.1 to 10 hours. It is preferable to perform this immersion while swinging and/or rotating the ceramic substrate and while agitating the electroless plating solution.

The electroless plating solution in which the substrate is immersed may have a bath temperature of, for example, approximately 40 to 85° C., and preferably approximately 60 to 80° C., and a pH of, for example, 5.5 to 14, and preferably 10 or more (e.g., a pH of 10 to 13). Furthermore, before the plating, a film of the matrix metal such as platinum having a thickness of approximately 2 to 10 nm may be formed as a catalyst core of the electroless plating, using a sputtering apparatus. Moreover, subsequently, a catalyst core pattern having a size of 2×2 mm or the like may be formed by immersing the substrate in a resist stripping solution or the like, after which “plating” is performed.

Note that the ceramic substrate on which a plating film (noble metal coating) is to be formed may be manufactured, for example, by layering and then firing ceramic green sheets, or by performing powder compacting and shaping and then firing a ceramic material.

<Thermal Treatment Step>

After the plating step, for example, in order to remove impurities contained in the plating film in the form of gas, the ceramic substrate on which the noble metal coating has been manufactured may be thermally treated at no less than a treatment temperature at which grain growth of the metal contained in the noble metal coating starts. “No less than the temperature at which grain growth of the matrix metal starts” may refer to a temperature of Tm/3 (K) or more, or Tm/2 (K) or more. Here, Tm refers to the temperature at which grains of the metal contained as a main component of the matrix metal grow. The grain growth may be also referred to as crystal grain growth. If the noble metal coating is, for example, fired at 800° C. to 1500° C. for approximately 1 to 5 hours after the film formation, impurities contained in the coating are removed in the form of gas.

<Surface Roughening Step>

The method for manufacturing the noble metal coating of the present invention may further include a surface roughening step of performing surface roughening treatments on the ceramic substrate before the plating step. The “surface roughening treatments” refers to a process that makes a surface of the ceramic substrate rough, and can be performed, for example, by roughening a ceramic substrate before firing using a nanoimprint technique, or by treating a ceramic substrate after firing using an acid such as hydrofluoric acid. The surface roughening treatments may be performed either before or after firing the ceramic substrate.

(3) Laminate

A laminate of the present invention includes the above-described noble metal coating, and a ceramic substrate. As the ceramic substrate, those shown as examples in the above description may be used. In the laminate of the present invention, the adhesive strength between the noble metal coating and the ceramic substrate is, for example, 1.5 N/mm² or more, preferably 2.50 N/mm² or more, more preferably 4.0 N/mm² or more, and particularly preferably 5.2 N/mm² or more, according to measurement by the Sebastian method. Furthermore, the noble metal coating has a coverage of 80% or more, preferably 90% or more, more preferably 95% or more, and particularly preferably 99% or more, even when thermal treatments are performed at no less than the temperature at which grain growth of matrix metal particles starts.

The laminate of the present invention is preferably thermally treated at no less than the temperature at which grain growth of the matrix metal starts. In this example, “no less than the temperature at which grain growth of the matrix metal starts” is as described above. If the laminate is, for example, fired at 1000° C. to 1500° C. for approximately 1 to 5 hours, impurities contained in the noble metal coating are removed in the form of gas.

Since the laminate of the present invention has a film thickness that is as thin as less than 2 μm, even when an expensive matrix metal is used, the material cost can be reduced. Furthermore, the laminate of the present invention is useful as a wiring board, an oxygen sensor, and the like, because the adhesion of the noble metal coating to the ceramic substrate can be maintained even when thermal treatments are performed at no less than the temperature at which grain growth of the matrix metal starts.

The laminate of the present invention may further includes a ceramic layer, on a surface of the noble metal coating on the side opposite to the ceramic substrate. In this case, there is no particular limitation on the ceramic layer, but specific examples thereof include layers containing various functional materials using a metal coating as an electrode, such as a dielectric material, a piezoelectric/electrostrictive material, a pyroelectric material, a thermoelectric converter material, a semiconductor material, a superconductor material, and an optical material. The dielectric material includes ferroelectric materials. Examples of the dielectric material include lead zirconate titanate and barium titanate.

The laminate of the present invention may be a dielectric element, a piezoelectric/electrostrictive element, a pyroelectric element, a thermoelectric element, a semiconductor element, a superconductor element, or an ion conductor element, in which the noble metal coating and the ceramic layer are co-fired. The co-firing temperature may be, for example, any temperature of 1700° C. or less (e.g., 1000 to 1700° C.). With the co-firing, the adhesion between the electrode film and the ceramic layer can be increased. In spite of the film thickness of the noble metal coating being as thin as less than 2 μm, since the matrix metal contains the ceramic fine particles, the grain boundary migration of matrix metal particles is pinned, for example, by the ceramic fine particles functioning as fillers even in such firing at a high temperature. Accordingly, the grain growth is suppressed, and, thus, the noble metal coating and the ceramic layer can be co-fired.

According to the laminate of the present invention, a plating film can be used as an electrode film in a ceramic electronic component such as a dielectric element, a piezoelectric/electrostrictive element, a pyroelectric element, a thermoelectric element, a semiconductor element, a superconductor element, an ion conductor element, or a gas sensor, and the electrode can be made thin. Thus, it is possible to reduce the material cost while maintaining or improving the characteristics.

(4) Method For Manufacturing Laminate

A method for manufacturing the laminate of the present invention includes: a ceramic layer forming step of forming a ceramic layer, on a surface of the noble metal coating on the side opposite to the ceramic substrate, the noble metal coating being manufactured by the method for manufacturing the above-described noble metal coating; and a co-firing step of co-firing the noble metal coating and the ceramic layer. As the ceramic layer, those shown as examples in the above description may be used.

<Ceramic Layer Forming Step>

In the ceramic layer forming step, a ceramic layer may be formed by layering ceramic green sheets, or by applying a ceramic paste. The paste contains a ceramic material and a binder. As the binder, for example, butyral resin, cellulose resin, acrylic resin, and the like may be used. The binder may be a mixture of a plurality of types of binders. There is no particular limitation on the method for applying the ceramic paste, but examples thereof include: wet-type application such as spin coating, slit coating, roll coating, sol-gel method, spraying method, and screen printing method; and electrophoresis where the noble metal coating is used as an electrode; and the like.

<Co-Firing Step>

In the co-firing step, the noble metal coating and the ceramic layer are co-fired. The co-firing is performed, for example, at any temperature of 1700° C. or less. With this step, it is possible to manufacture a laminate, for example, for a ceramic electronic component such as a dielectric element, a piezoelectric/electrostrictive element, a pyroelectric element, a thermoelectric element, a semiconductor element, a superconductor element, an ion conductor element, or a sensor, in which the adhesion between the noble metal coating and the ceramic layer is excellent.

### EXAMPLES

Hereinafter, examples of the present invention will be described, but the present invention is not limited to examples described below.

### Example 1

Surface roughening treatments were performed using hydrofluoric acid on a surface of a zirconia substrate having a size of 30 mm×20 mm and a thickness of 0.2 mm.

A resist pattern in which the surface of the substrate was exposed in a size of 2×2 mm was formed by applying a negative-type photoresist PMER-N (manufactured by Tokyo Ohka Kogyo Co., Ltd.) to the roughened surface of the substrate, and exposing and developing the substrate.

Next, a Pt film having a thickness of 5 nm was formed via the resist pattern, as a catalyst core of the electroless plating, using a magnetron sputtering apparatus (manufactured by Anelva). Subsequently, a Pt catalyst core pattern in a size of 2×2 mm was formed by immersing the substrate in a resist stripping solution.

Then, an electroless Pt plating solution (Lectroless Pt100, manufactured by Electroplating Engineers of Japan Ltd.) was adjusted such that a metal film having a thickness of 0.5 μm was formed. A composite plating solution was manufactured by adding 15 parts by weight of ceria particle dispersing liquid having an average particle size of 50 nm, in which the pH was adjusted in advance to 11 and the solid content to 20%, to 100 parts by weight of this plating solution, and adjusting the pH to 12 with ammonia such that the particles were dispersed. The substrate was immersed in the composite plating solution in which the bath temperature was kept at 64° C. and the pH was kept at 12, and allowed to stand for 20 minutes with agitation. In this manner, a zirconia substrate was obtained in which a Pt film having a size of 2×2 mm was formed on the roughened surface. The content of the ceria particles in the Pt film was 5 parts by weight with respect to 100 parts by weight of Pt.

in order to remove gas from the obtained Pt film, the zirconia substrate was thermally treated in air, at a programming rate of 50° C./min and a maximum temperature of 1100° C., for a hold time of 2 hours.

### Example 2

A Pt film was manufactured on a zirconia substrate as in Example 1, except that a composite plating solution was manufactured as in Example 1 in conditions where particles added to the plating solution were changed to zirconia particles.

### Example 3

A Pt film was manufactured on a zirconia substrate as in Example 1, except that a composite plating solution was manufactured as in Example 1 in conditions where particles added to the plating solution were changed to yttria particles.

### Example 4

A Pt film was manufactured on a zirconia substrate as in Example 1, except that a composite plating solution was manufactured as in Example 1 in conditions where particles added to the plating solution were changed to alumina particles.

### Example 5

A Pt film was manufactured on a zirconia substrate as in Example 1, except that a composite plating solution was manufactured as in Example 1 in conditions where particles added to the plating solution were changed to titania particles.

### Example 6

A Pt film was manufactured on a zirconia substrate as in Example 1, except that a composite plating solution was manufactured as in Example 1 in conditions where particles added to the plating solution were changed to spinel particles.

### Comparative Example 1

A film was formed as in Example 1, without adding particles.

### Comparative Example 2

A pattern having a size of 2×2 mm and a thickness of 0.5 μm was formed by the screen printing method using a Pt paste (manufactured by Tanaka Kikinzoku Kogyo) on a zirconia substrate having a size of 30 mm×20 mm and a thickness of 0.2 mm, and fired at 1350° C., and, thus, a Pt film was formed.

### Comparative Example 3

A pattern having a size of 2×2 mm and a thickness of 10.5 μm was formed by the screen printing method using a Pt paste (manufactured by Tanaka Kikinzoku Kogyo) on a zirconia substrate having a size of 30 mm×20 mm and a thickness of 0.2 mm, and fired at 1350° C., and, thus, a Pt film was formed.

The following tests were performed on samples of Examples 1 to 6 and Comparative Examples 1 to 3. Table 1 shows the results.

(1) Coverage

The coverage was obtained by image analysis through transmitted light observation on the obtained ceramic substrates using a microscope.

(2) Adhesive Strength

The adhesive strength of the metal coating was measured by the Sebastian method on samples that were not defective in appearance.

First, each of 2×2 mm metal films formed by plating was joined with an aluminum wire by soldering. The substrate was fixed on a tension tester, the aluminum wire joined with the metal film was pulled, and the load applied when the metal film was separated from the substrate was measured.

(3) Cross Sectional Microstructure

The cross sectional microstructure of the laminates was observed using an FE-SEM (manufactured by JEOL).

### RESULTS

Table 1 shows that, in the case of composite plating, the coverage after the thermal treatments is high, and the adhesive strength has been improved.

Furthermore, the observation of the cross sectional microstructure showed that ceramic particles are present at the grain boundary of the metal film, and the metal film is configured by fine crystal grains. It was particularly shown that no void is formed at recess portions formed by the surface roughening treatments, and the anchoring effect is maintained.

TABLE 1

| | | Adhesive Strength On Flat Face |
|---|---|---|
| | Coverage | N/mm² |
| Ex. 1 | 100% | 6.4 |
| Ex. 2 | 99% | 5.3 |
| Ex. 3 | 99% | 4.9 |
| Ex. 4 | 99% | 5.1 |
| Ex. 5 | 98% | 4.4 |
| Ex. 6 | 99% | 5.1 |
| Com. Ex. 1 | 100% | Unmeasurable |
| Com. Ex. 2 | 75% | 1.1 |
| Com. Ex. 3 | 90% | 1.2 |

The Pt films of Examples 1 to 6 each had a film thickness that is as thin as 0.5 μm, a coverage of 98% or more, and a high adhesive strength on flat faces. This result on Pt is applicable to noble metals other than Pt. Accordingly, when a dielectric element, a piezoelectric/electrostrictive element, a pyroelectric element, a thermoelectric element, a semiconductor element, a superconductor element, an ion conductor element, or a sensor is formed by further forming a ceramic layer on the noble metal coating, and co-firing the noble metal coating and the ceramic layer, a ceramic element with improved characteristics, in which the influence of the electrode is reduced, can be manufactured.

What is claimed is:

1. A noble metal coating formed on a ceramic substrate, the noble metal coating having a thickness of less than 2 μm and comprising:
a matrix metal including at least one metal selected from a group consisting of Pt, Pd, Ru, Rh, Os, Ir and Au as a main component; and
a ceramic fine particle.

2. The noble metal coating of claim 1, wherein said ceramic fine particle contains at least one ceramic selected from a group consisting of coria, zirconia, yttria, alumina, titania, spinel (magnesium aluminate, nickel aluminate), yttria-stabilized zirconia, ceria-stabilized zirconia, TiC, and TiN.

3. The noble metal coating of claim 1, wherein a content of said ceramic fine particle is 3 to 30 parts by weight with respect to 100 parts by weight of said matrix metal.

4. The noble metal coating of claim 1, wherein an average particle size of said ceramic fine particle is 5 to 100 nm.

5. The noble metal coating of claim 1, wherein a ratio between said average particle size of said ceramic fine particle and said thickness of said noble metal coating is 1/1.5 to 1/400.

6. The noble metal coating of claim 1, thermally treated at a temperature which is greater than or equal to a particle growth initiating temperature for said matrix metal in said noble metal coating.

7. The noble metal coating of claim 1, formed by plating.

8. A method for manufacturing a noble metal coating according to claim 1, comprising:
a dispersion step of dispersing said ceramic fine particle in a plating solution that contains a metal ion corresponding to said matrix metal; and
a plating step of forming said noble metal coating having a thickness of less than 2 μm on said ceramic substrate using said plating solution in which said ceramic fine particle is dispersed.

9. The method for manufacturing the noble metal coating of claim 8, further comprising a thermal treatment step of performing a thermal treatment at a temperature which is greater than or equal to a particle growth initiating temperature for said matrix metal.

10. The method for manufacturing the noble metal coating of claim 8, further comprising a surface roughening step of performing a surface roughening treatment on said ceramic substrate before said plating step.

11. The method for manufacturing the noble metal coating of claim 8, wherein a pH of said plating solution in said plating step is 10 to 14.

12. The method for manufacturing the noble metal coating of claim 8, wherein a temperature of said plating solution is 30 to 85° C.

13. A laminate, comprising:
a noble metal coating according to claim 1; and
a ceramic substrate.

14. The laminate of claim 13, further comprising a ceramic layer on a surface of said noble metal coating in an opposite side to said ceramic substrate,
wherein said noble metal coating and said ceramic layer are co-fired, and
wherein said laminate is a dielectric element, a piezoelectric/electrostrictive element, a pyroelectric element, a thermoelectric element, a semiconductor element, a superconductor element, or an ion conductor element.

15. A method for manufacturing a laminate according to claim 14, comprising:
a dispersion step of dispersing said ceramic fine particle in a plating solution that contains a metal ion corresponding to said matrix metal;
a plating step of forming said noble metal coating having a thickness of less than 2 μm on said ceramic substrate using said plating solution in which said ceramic fine particle is dispersed;
a ceramic layer forming step of forming said ceramic layer on a surface of said noble metal coating in an opposite side to said ceramic substrate; and
a co-firing step of co-firing said noble metal coating and said ceramic layer.

16. The noble metal coating of claim 2, wherein a content of said ceramic fine particle is 3 to 30 parts by weight with respect to 100 parts by weight of said matrix metal.

17. The noble metal coating of claim 2, wherein an average particle size of said ceramic fine particle is 5 to 100 nm.

18. The noble metal coating of claim 3, wherein an average particle size of said ceramic fine particle is 5 to 100 nm.

19. The noble metal coating of claim 2, wherein a ratio between said average particle size of said ceramic fine particle and said thickness of said noble metal coating is 1/1.5 to 1/400.

20. The noble metal coating of claim 3, wherein a ratio between said average particle size of said ceramic fine particle and said thickness of said noble metal coating is 1/1.5 to 1/400.
